(19) United States
(12) Patent Application Publication
(10) Pub. No.: US 2026/0040571 A1
(43) Pub. Date: Feb. 5, 2026

(54) PLATE ROUTING ARCHITECTURE FOR MULTIPLE DECK MEMORY

(71) Applicant: Micron Technology, Inc., Boise, ID (US)

(72) Inventors: Veeresh Salimath, Folsom, CA (US); Makoto Kitagawa, Folsom, CA (US); Mark Fischer, Boise, ID (US)

(21) Appl. No.: 18/790,870

(22) Filed: Jul. 31, 2024

(51) Int. Cl. H10B 53/20; H10B 53/40

(52) U.S. Cl. CPC H10B 53/20; H10B 53/40

(57) ABSTRACT

A memory array can include upper and lower decks of memory cells, such as ferroelectric random access memory (FeRAM) memory cells. The lower deck of memory cells can be positioned between the upper deck and a substrate. A first plate line associated with the lower deck of memory cells can be coupled with charge storage components of the lower deck of memory cells, and the first plate line can be positioned between the lower deck of memory cells and the upper deck of memory cells. A first contact includes an upper contact portion and a lower contact portion. The upper contact portion can be coupled to the first plate line and can extend laterally away from the first plate line and from the lower deck of memory cells. The lower contact portion can be coupled between the upper contact portion and the substrate.

### BACKGROUND

Memory devices are widely used to store information in various electronic devices such as computers, wireless communication devices, cameras, digital displays, and the like. Information is stored by programing different states of a memory device. For example, binary devices have two states, often denoted by a logic “1” or a logic “0.” In some systems, more than two states can be stored. To access the stored information, a component of the electronic device can read, or sense, the stored state in the memory device. To store information, a component of the electronic device can write, or program, the state in the memory device.

Various types of memory devices exist, including magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices can be volatile or non-volatile. Non-volatile memory, e.g., FeRAM, can maintain a stored logic state for extended periods of time in the absence of an external power source. Volatile memory devices, e.g., DRAM, can lose stored state information over time unless they are periodically refreshed by an external power source. FeRAM can use similar device architectures as volatile memory but can have non-volatile properties due to the use of a ferroelectric capacitor as a storage device. FeRAM devices can thus have improved performance compared to other non-volatile and volatile memory devices.

Improving memory devices, generally, can include increasing memory cell density, increasing read/write speeds, increasing reliability, increasing data retention, reducing power consumption, or reducing manufacturing costs, among other metrics.

### BRIEF DESCRIPTION OF THE DRAWINGS

In the drawings, which are not necessarily drawn to scale, like numerals can describe similar components in different views. Like numerals having different letter suffixes can represent different instances of similar components. The drawings illustrate generally, by way of example, but not by way of limitation, various embodiments discussed in the present document.

FIG. 1 illustrates an example of a memory device.

FIG. 2 illustrates an example of a portion of a memory device including a memory cell.

FIG. 3A-3B illustrate an example of hysteresis curves that support plate line configurations and operations for a memory array.

FIG. 4A illustrates generally a first cross-section view of an example of a portion of a memory device.

FIG. 4B illustrates generally a second cross-section view of an example of a portion of a memory device.

FIG. 5 illustrates generally a cross-section view of an example of a portion of a memory device with an overlapping plate line contact.

FIG. 6A illustrates generally a first example of multiple instances of overlapping plate line contacts.

FIG. 6B illustrates generally a second example of multiple instances of overlapping plate line contacts.

FIG. 7 illustrates generally an example of a method that includes forming an overlapping contact in a lower deck of a memory device.

### DETAILED DESCRIPTION

In some memory arrays, multiple decks of memory cells can be positioned above a substrate. The substrate can include various support components used to operate the memory array including, for example, decoders, amplifiers, drivers, etc. A memory device can include one type or multiple types of arrays or memory cells. For example, a first deck of a device can comprise ferroelectric memory cells (e.g., FeRAM) and a second deck of the same device can comprise other FeRAM memory cells, and the first deck can be stacked on top of the second deck. In another example, a first deck of a device can comprise FeRAM memory cells and a second deck of the same device can comprise DRAM cells.

In an example, an upper deck of memory cells (e.g., comprising FeRAM cells) can be stacked on top of a lower deck of memory cells (e.g., comprising FeRAM cells). Contacts for the components of the upper deck and the lower deck can be routed separately or together to the substrate. In an example, contacts used by the upper deck can pass through regions that could otherwise be used for components of the lower deck of memory cells. In some examples, one or more areas of the lower deck can be allocated to connectors or sockets that couple upper deck contacts, plate lines, and other components to the substrate. In an example, the contacts for components of the upper deck can be routed around a periphery of the lower deck.

Contacts for components of the lower deck can be routed to the substrate. Due to processing or fabrication limitations, some contacts that service the lower deck can be routed away from the substrate and toward the upper deck, and then routed to the periphery of the lower deck before contacting the substrate. For example, one or more plate lines that service the lower deck can be routed up, away from the substrate, and toward other plate lines that service the upper deck. Such lower deck plate lines can thus have a relatively longer signal path than their upper deck plate line counterparts, despite the lower deck plate lines originating closer to the substrate (e.g., and thus close to associated drive circuitry at the substrate) than the upper deck plate lines.

The present inventors have recognized, among other things, that a problem to be solved includes efficiently routing lower deck plate lines to a substrate of a multiple-deck memory device. A solution can include or use a plate line contact that extends over a side edge portion of a plate line and toward the substrate, such as at or adjacent to a periphery of the lower deck. In an example, the solution includes an overlapping contact that includes a contact portion that electrically couples to a top of a plate line and extends laterally away from the plate line and laterally away from an array region of the lower deck. The lateral extension portion of the contact can couple with a via or other contact portion that extends down through one or more layers, such as to the substrate, to couple the lower deck plate line to corresponding drive circuitry using a shortest signal path.

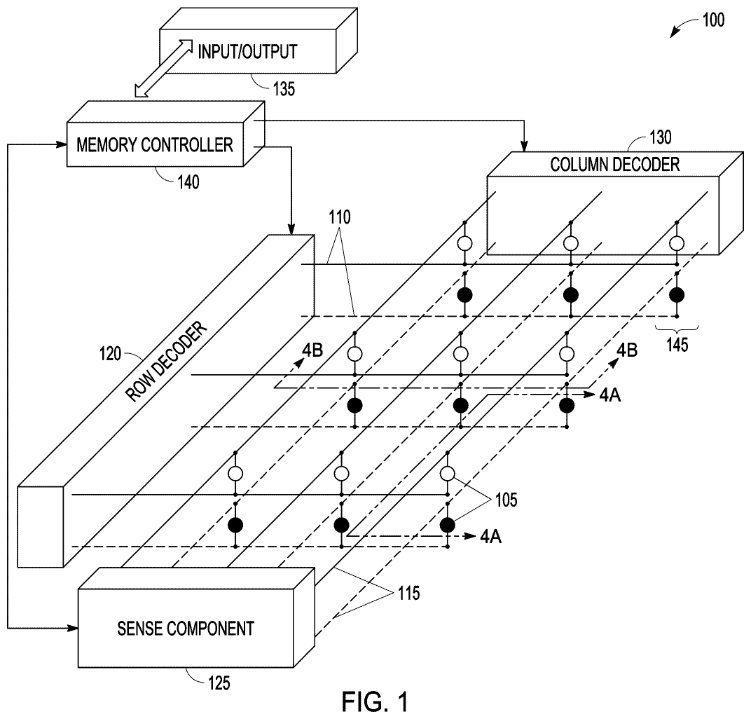

FIG. 1 illustrates generally an example of a memory device 100. The memory device 100 can be referred to as an electronic memory apparatus. The memory device 100 includes memory cells 105 that are programmable to store different states. Each memory cell can be programmable to store two states, denoted as a logic 0 and a logic 1. In some cases, one or more of the memory cells 105 can be configured to store more than two logic states. The memory cells 105 can store charges representative of the programmable states in a capacitor; for example, a charged and uncharged capacitor can represent two logic states, respectively. DRAM architectures can use such a design, and the capacitor used can include a dielectric material with linear or para-electric polarization properties as the insulator. By contrast, a ferroelectric memory cell can include a capacitor with a ferroelectric material provided as the insulating material. Different levels of charge of a ferroelectric capacitor can represent different logic states. Ferroelectric materials have non-linear polarization properties. Some details and advantages of a ferroelectric memory cell are discussed below.

The memory device 100 can be a three-dimensional (3D) memory array, where two-dimensional (2D) memory arrays are formed on top of one another. This configuration can increase the number of memory cells that can be formed on a single die or substrate as compared with 2D arrays, which in turn can reduce production costs or increase the performance of the memory array, or both. According to the example of FIG. 1, the memory device 100 includes two levels of the memory cells 105 and can thus be considered a three-dimensional memory array. The number of levels is not limited to two. In an example, each level can be aligned or positioned such that the memory cells 105 can be approximately aligned with one another across each level, forming a memory cell stack 145 or column.

Each row of the memory cells 105 is connected to an access line, or word line 110, and each column of the memory cells 105 is connected to a bit line or digit line 115. Each of the word lines 110 and bit lines 115 can be substantially perpendicular to one another to create an array. Each row of the memory cells 105 can be coupled to plate lines (not shown in the example of FIG. 1). As used herein, the terms plate node, plate line, or simply plate can be used interchangeably.

In the example of FIG. 1, each of the memory cells 105 of a particular memory cell stack 145 can be coupled to separate conductive lines such as the bit lines 115. In other examples (not shown), two of the memory cells 105 in a memory cell stack 145 can share a common bit line 115. That is, a bit line 115 can be in electronic communication with the bottom electrode of an upper memory cell and the top electrode of a lower memory cell. Other configurations can be used, for example, a third deck can share a word line 110 with a lower deck. In general, a particular memory cell can be located at the intersection of two conductive lines such as a word line 110 and a digit line 115. This intersection can be referred to as an address of the particular memory cell. A target memory cell of the memory cells 105 can be a memory cell located at the intersection of an energized word line 110 and digit line 115. That is, in an example, the word line 110 and the digit line 115 can be energized to read or write the target memory cell at their intersection. Other memory cells that are in electronic communication with (e.g., connected to) the same word line 110 or digit line 115 can be referred to as untargeted memory cells.

Respective electrodes can be coupled to a memory cell and its corresponding word line 110 and digit line 115. An electrode can include, for example, an electrical conductor that can be used as an electrical contact for one or more of the memory cells 105. An electrode can include a trace, wire, conductive line, conductive layer, or the like that provides a conductive path between elements or components of the memory device 100.

Operations such as reading and writing can be performed on memory cells 105 by activating or selecting the word lines 110 and digit lines 115. References herein to access lines, word lines, digit lines, and/or bit lines, or their analogues, are interchangeable without loss of understanding or operation. Activating or selecting a word line 110 or a digit line 115 can include applying a voltage to the respective line. The word lines 110 and digit lines 115 can be made of conductive materials such as metals (e.g., copper (Cu), aluminum (Al), gold (Au), tungsten (W), etc.), metal alloys, carbon, conductively doped semiconductors, or other conductive materials, alloys, compounds, or the like.

In some architectures, the logic storing device of a cell, e.g., a capacitor, can be electrically isolated from a digit line by a selection component. A word line 110 can be connected to and can control the selection component. For example, the selection component can be a transistor and the word line 110 can be connected to the gate of the transistor. Activating the word line 110 provides an electrical connection or closed circuit between the capacitor of a particular memory cell and its corresponding digit line 115. The digit line 115 can then be accessed to either read or write the memory cell. Upon selecting a memory cell, the resulting signal can be used to determine the stored logic state.

Access to the memory cells 105 can be controlled using a row decoder 120 and a column decoder 130. The row decoder 120 can receive a row address from a memory controller 140 and activate an appropriate one of the word lines 110 based on the received row address. Similarly, a column decoder 130 can receive a column address from the memory controller 140 and activate an appropriate one of the digit lines 115. In an example, the memory device 100 includes multiple word lines 110 and multiple digit lines 115. Thus, by activating a particular word line and a particular digit line, a corresponding memory cell at their intersection can be accessed.

Upon accessing, a particular memory cell of the memory cells 105 can be read, or sensed, by or using a sense component 125 to determine the stored state of the particular memory cell. For example, after accessing the particular memory cell, a ferroelectric capacitor of the memory cell can discharge to its corresponding digit line 115. Discharging the ferroelectric capacitor can result from biasing, or applying a voltage to, the ferroelectric capacitor. The discharging can cause a change in the voltage of the digit line 115, which the sense component 125 can compare to a reference voltage (not shown) to thereby determine the stored state of the particular memory cell.

The sense component 125 can include various transistors or amplifiers configured to detect and amplify a difference in the signals, which can be referred to as latching. The detected logic state of a memory cell can then be provided as an output 135. In an example, the sense component 125 can comprise a portion of the column decoder 130 or row decoder 120. In an example, the sense component 125 can be connected to or in electronic communication with the column decoder 130 or row decoder 120. In an example, unselected or untargeted memory cells can be shunted to the plate to mitigate unwanted transient voltages.

In some memory architectures, accessing a memory cell can degrade or destroy the stored logic state and re-write or refresh operations can be performed to return the original logic state to the same memory cell. In DRAM, for example, the cell capacitor can be partially or completely discharged during a sense operation, corrupting the stored logic state. In this case, the logic state can be re-written after a sense operation. In an example, activating a single word line can result in the discharge of all memory cells in the corresponding row and thus several or all the memory cells in the row can be re-written. In non-volatile memory, such as comprising an array that includes or uses ferroelectrics, accessing a memory cell may not destroy or corrupt the logic state and, accordingly, the memory cell may not require re-writing after accessing. In some examples, multiple levels of memory cells can be coupled to the same plate. Such a plate configuration can result in a smaller amount of area used to connect higher level memory cells to the substrate.

Some memory architectures, including DRAM, can lose their stored state over time unless they are periodically refreshed by an external power source. For example, a charged capacitor can become discharged over time through leakage currents, resulting in loss of the stored information. The refresh rate of these so-Called volatile memory devices can be relatively high, e.g., tens of refresh operations per second for DRAM arrays, which can result in significant power consumption. With increasingly larger memory arrays, increased power consumption can inhibit the deployment or operation of memory arrays (e.g., power supplies, heat generation, material limits, etc.), especially for mobile devices that rely on a finite power source, such as a battery. As discussed herein, ferroelectric memory cells can have beneficial properties that can result in improved performance relative to other memory architectures.

In an example, the memory controller 140 can control operations (e.g., read, write, re-write, refresh, decharge, etc.) of the memory cells 105 through or using the various components of the memory device 100, for example, the row decoder 120, column decoder 130, and sense component 125. In some examples, one or more of the row decoder 120, column decoder 130, and sense component 125 can be co-located with the memory controller 140. The memory controller 140 can generate row and column address signals in order to activate the desired word line 110 and digit line 115. The memory controller 140 can generate and control various voltages or currents used during the operation of the memory device 100. For example, it can apply discharge voltages to a word line or digit line after accessing one or more of the memory cells 105. In general, the amplitude, shape, or duration of an applied voltage or current discussed herein can be adjusted or varied and can be different for the various operations discussed in operating memory device 100. Furthermore, one, multiple, or all the memory cells 105 of the memory device 100 can be accessed simultaneously; for example, multiple or all cells of the memory device 100 can be accessed simultaneously during a reset operation in which all the memory cells 105, or a group of the memory cells 105, are set to a single logic state.

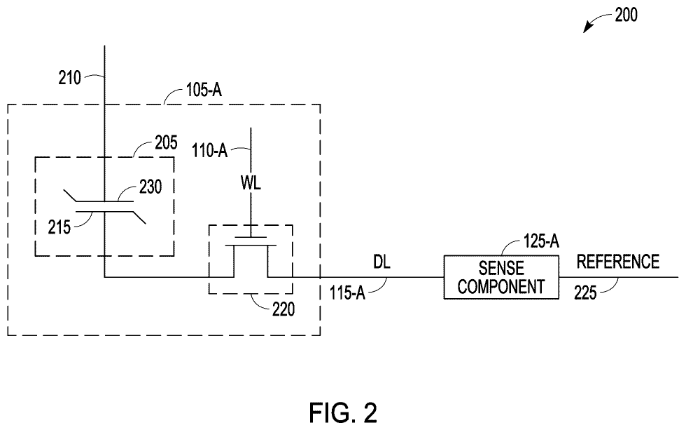

FIG. 2 illustrates generally an example of circuit 200 that can include or use a memory cell. The circuit 200 includes a memory cell 105-A, a word line 110-A, a digit line 115-A, and sense component 125-A, which can be examples of a memory cell of the memory cells 105, word line 110, digit line 115, and sense component 125, respectively, as described with reference to FIG. 1.

The memory cell 105-A can include a logic storage component, such as capacitor 205 that has a first plate, cell plate 230, and a second plate, cell bottom 215. The cell plate 230 and cell bottom 215 can be capacitively coupled through a ferroelectric material positioned between the plates. The orientation of cell plate 230 and cell bottom 215 can be flipped without changing the operation of memory cell 105-A.

The circuit 200 includes a selection component 220 and reference line 225. The cell plate 230 can be accessed via a plate line 210 and the cell bottom 215 can be accessed via the digit line 115-A. In some examples, memory cell 105-A can share access lines (e.g., digit lines, word lines, plate lines) with other memory cells. For example, the digit line 115-A can be shared with other memory cells in a same column as the memory cell 105-A, the word line 110-A can be shared with other memory cells in a same row as the memory cell 105-A, and the plate line 210 can be shared with other memory cells in the same section, tile, deck, or other combination of memory cells as the memory cell 105-A. Various states can be stored by charging or discharging the capacitor 205. In various examples, a peripheral contact can be used to route or couple the digit line 115-A or plate line 210 or other access line of upper levels of memory cells to a substrate positioned below the arrays of memory cells.

The stored state of the capacitor 205 can be read or sensed by operating various elements represented in circuit 200. In an example, the capacitor 205 can be in electronic communication with the digit line 115-A. For example, the capacitor 205 can be isolated from the digit line 115-A when selection component 220 is deactivated, and the capacitor 205 can be connected to the digit line 115-A when the selection component 220 is activated. Activating the selection component 220 can be referred to as selecting the memory cell 105-A. In some examples, the selection component 220 is a transistor and its operation is controlled by applying a voltage to the transistor gate, where the voltage magnitude is greater than the threshold magnitude of the transistor. The word line 110-A can be used to activate the selection component 220; for example, a voltage applied to the word line 110-A can be applied to the transistor gate, connecting the capacitor 205 with the digit line 115-A. The particular access operations (e.g., read operation or write operation) can be modified based on the plate configuration of the memory array.

In other examples, positions of the selection component 220 and capacitor 205 can be switched, such that the selection component 220 is connected between the plate line 210 and the cell plate 230 and such that the capacitor 205 is between the digit line 115-A and the other terminal of the selection component 220. In this embodiment, the selection component 220 can be in electronic communication with the digit line 115-A through the capacitor 205. This configuration can be associated with alternative timing and biasing for read and write operations.

In an example that includes a ferroelectric material provided between the plates of the capacitor 205, the capacitor 205 may not discharge upon connection to the digit line 115-A. In one example, to sense the logic state stored by the ferroelectric capacitor 205, the word line 110-A can be biased to select the memory cell 105-A and a voltage can be applied to the plate line 210. In some examples, the digit line 115-A can be virtually grounded and then isolated from the virtual ground, which can be referred to as “floating,” prior to biasing the plate line 210 and the word line 110-A. Biasing the plate line 210 can result in a voltage difference (e.g., the plate line 210 voltage minus the digit line 115-A voltage) across the capacitor 205. The voltage difference can yield a change in the stored charge on the capacitor 205, where the magnitude of the change in stored charge can depend on the initial state of the capacitor 205 (i.e., whether the initial state stored a logic 1 or a logic 0). This can cause a change in the voltage of the digit line 115-A based on the charge stored on the capacitor 205.

A change in voltage of the digit line 115-A can depend on its intrinsic capacitance. That is, as charge flows through the digit line 115-A, some finite charge can be stored in the digit line 115-A and the resulting voltage depends on the intrinsic capacitance. The intrinsic capacitance can depend on physical characteristics, including the dimensions, of the digit line 115-A. The digit line 115-A can connect many of the memory cells 105 so the digit line 115-A can have a length that results in a non-negligible capacitance (e.g., on the order of picofarads (pF)). The resulting voltage of the digit line 115-A can then be compared to a reference (e.g., a voltage of reference line 225) using the sense component 125-A to determine the stored logic state in the memory cell 105-A. Other sensing processes can similarly be used.

The sense component 125-A can include various transistors or amplifiers to detect and amplify a difference in signals, which can be referred to as latching. The sense component 125-A can include a sense amplifier that receives and compares the voltage of the digit line 115-A and the reference line 225. The sense amplifier output can be driven to a higher (e.g., a positive) or lower (e.g., negative or ground) supply voltage based on the comparison. For instance, if the digit line 115-A has a higher voltage than the reference line 225, then the sense amplifier output can be driven to a positive supply voltage. In some cases, the sense amplifier can drive the digit line 115-A to the supply voltage. The sense component 125-A can then latch the output of the sense amplifier and/or the voltage of the digit line 115-A, which can be used to determine the stored state in the memory cell 105-A, e.g., logic 1. Alternatively, if the digit line 115-A has a lower voltage than the reference line 225, then the sense amplifier output can be driven to a negative or ground voltage. The sense component 125-A can similarly latch the sense amplifier output to determine the stored state in the memory cell 105-A, e.g., logic 0. The latched logic state of the memory cell 105-A can then be output, for example, through the column decoder 130 as the output 135.

To write the memory cell 105-A, a voltage can be applied across the capacitor 205. Various methods can be used. In one example, the selection component 220 can be activated through the word line 110-A to electrically connect the capacitor 205 to the digit line 115-A. A voltage can be applied across the capacitor 205 by controlling the voltage of the cell plate 230 (through the plate line 210) and the cell bottom 215 (through the digit line 115-A). To write a logic 0, the cell plate 230 can be taken high, that is, a positive voltage can be applied to the plate line 210, and the cell bottom 215 can be taken low, e.g., by virtually grounding or applying a negative voltage to the digit line 115-A. The opposite process is performed to write a logic 1, where the cell plate 230 is taken low and the cell bottom 215 is taken high.

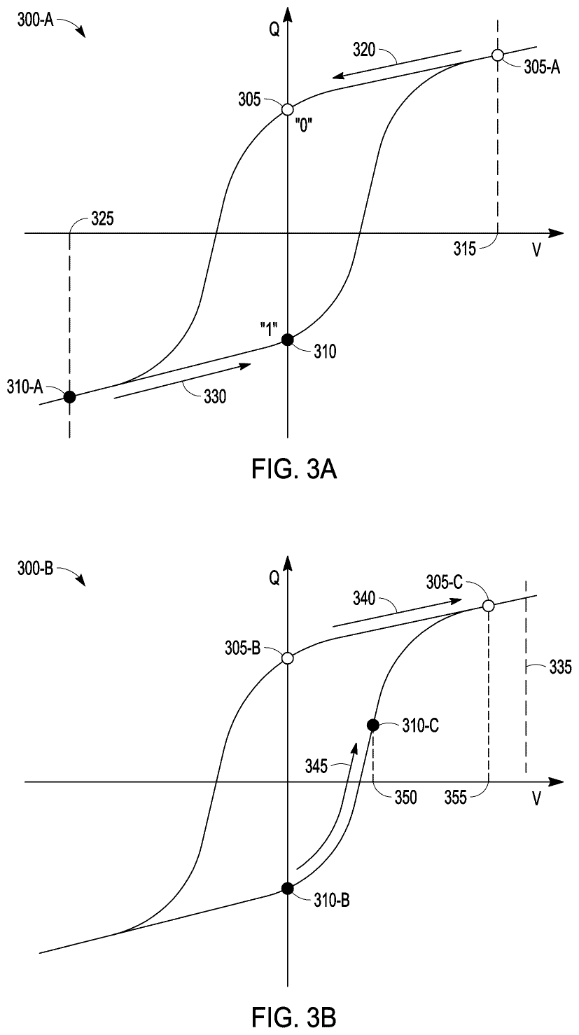

FIG. 3 illustrates an example of non-linear electrical properties with hysteresis curves 300-A and 300-B for a ferroelectric memory cell. The hysteresis curves 300-A and 300-B illustrate an example ferroelectric memory cell writing and reading process, respectively. The hysteresis curves 300-A and 300-B show a charge, Q, stored using a ferroelectric capacitor (e.g., the capacitor 205 of FIG. 2) as a function of a voltage difference, V.

A ferroelectric material can be characterized by a spontaneous electric polarization, i.e., it maintains a non-zero electric polarization in the absence of an electric field. Example ferroelectric materials include barium titanate (BaTiO3), lead titanate (PbTiO3), lead zirconium titanate (PZT), and strontium bismuth tantalate (SBT). The ferroelectric capacitors described herein can include these or other ferroelectric materials. Electric polarization within a ferroelectric capacitor results in a net charge at the surface of the ferroelectric material and attracts opposite charge through the capacitor terminals. Thus, charge can be stored at the interface of the ferroelectric material and the capacitor terminals. Because the electric polarization can be maintained in the absence of an externally applied electric field for relatively long times, charge leakage can be significantly decreased as compared with, for example, other types of capacitors employed in DRAM arrays. This can reduce the need to perform refresh operations as described above for some DRAM architectures.

The illustrated example of hysteresis curves 300-A and 300-B can be understood from the perspective of a single terminal of a capacitor. By way of example, if the ferroelectric material has a negative polarization, then positive charge accumulates at the terminal. Likewise, if the ferroelectric material has a positive polarization, then negative charge accumulates at the terminal. Additionally, it should be understood that the voltages in the hysteresis curves 300-A and 300-B represent a voltage difference across the capacitor and are directional. For example, a positive voltage can be realized by applying a positive voltage to the terminal in question (e.g., the cell plate 230) and maintaining the second terminal (e.g., the cell bottom 215) at ground (or approximately zero volts (OV)). A negative voltage can be applied by maintaining the terminal in question at ground and applying a positive voltage to the second terminal—i.e., positive voltages can be applied to negatively polarize the terminal in question. Similarly, two positive voltages, two negative voltages, or any combination of positive and negative voltages can be applied to the appropriate capacitor terminals to generate the voltage difference shown in the hysteresis curves 300-A and 300-B.

As depicted in the first hysteresis curve 300-A, a ferroelectric material can maintain a positive or negative polarization with a zero voltage difference, resulting in two possible charged states: a first state 305 and a second state 310. According to the example of FIG. 3, the first state 305 represents a logic 0 and the second state 310 represents a logic 1. In some examples, the logic values of the respective charge states can be reversed to accommodate other schemes for operating a memory cell.

A logic 0 or 1 can be written to the memory cell by controlling the electric polarization of the ferroelectric material, and thus the charge on the capacitor terminals, by applying voltage. For example, applying a net positive voltage 315 across the capacitor results in charge accumulation until a first charged state 305-A is reached. Upon removing the voltage 315, the first charged state 305-A follows a charge path 320 until it reaches the first state 305 at zero applied voltage. Similarly, the second state 310 can be written by applying a net negative voltage 325, which results in a second charged state 310-A. After removing the negative voltage 325, the second charged state 310-A follows a charge path 330 until it reaches the second state 310 at zero applied voltage. The first charged state 305-A and second charged state 310-A can be referred to as the remnant polarization (Pr) values, i.e., the polarization (or charge) that remains upon removing the external bias (e.g., voltage). The coercive voltage is the voltage at which the charge (or polarization) is zero.

To read, or sense, the stored state of a ferroelectric capacitor, a voltage can be applied across the capacitor. In response, the stored charge, Q, changes, and the degree of the change depends on the initial charge state—i.e., the final stored charge (Q) depends on whether a first state 305-B or second state 310-B was initially stored. For example, the second hysteresis curve 300-B illustrates two possible stored states 305-B and 310-B. A voltage 355 can be applied across the capacitor as discussed with reference to FIG. 2. In other cases, a fixed voltage can be applied to the cell plate and, although depicted as a positive voltage, the voltage 355 can be negative. In response to the voltage 355, the first state 305-B voltage can follow a charge path 340. Likewise, if the second state 310-B was initially stored, then the voltage can follow a charge path 345. The final position of the first state 305-C and second state 310-C depend on a number of factors, including the specific sensing scheme and circuitry.

In some examples, a final charge can depend on an intrinsic capacitance of the digit line connected to the memory cell. For example, if the capacitor is electrically connected to the digit line and the voltage 335 is applied, then the voltage of the digit line can rise due to its intrinsic capacitance. In this example, a voltage measured at a sense component may not equal the voltage 335 and instead can depend on the voltage of the digit line. The position of final first states 305-C and 310-C on the second hysteresis curve 300-B can thus depend on the capacitance of the digit line and can be determined through a load-line analysis—i.e., the first states 305-C and 310-C can be defined with respect to the digit line capacitance. As a result, the voltage of the capacitor, voltage 350 or voltage 355, can be different and can depend on the initial state of the capacitor.

By comparing the digit line voltage to a reference voltage, the initial state of the capacitor can be determined. The digit line voltage can be the difference between the voltage 335 and the final voltage across the capacitor, such as the voltage 350 or voltage 355—i.e., (voltage 335-voltage 350) or (voltage 335-voltage 355). A reference voltage can be generated such that its magnitude is between the two possible voltages of the two possible digit line voltages in order to determine the stored logic state—i.e., if the digit line voltage is higher or lower than the reference voltage. For example, the reference voltage can be an average of the two quantities, (voltage 335-voltage 350) and (voltage 335-voltage 355). Upon comparison by the sense component, the sensed digit line voltage can be determined to be higher or lower than the reference voltage, and the stored logic value of the ferroelectric memory cell (i.e., a logic 0 or 1) can be determined.

A ferroelectric memory cell can maintain its initial logic state after a read operation. For example, if the first state 305-B is stored, the charge state can follow charge path 340 to the first state 305-C during a read operation and, after removing the voltage 335, the charge state can return to initial first state 305-B by following the charge path 340 in the opposite direction.

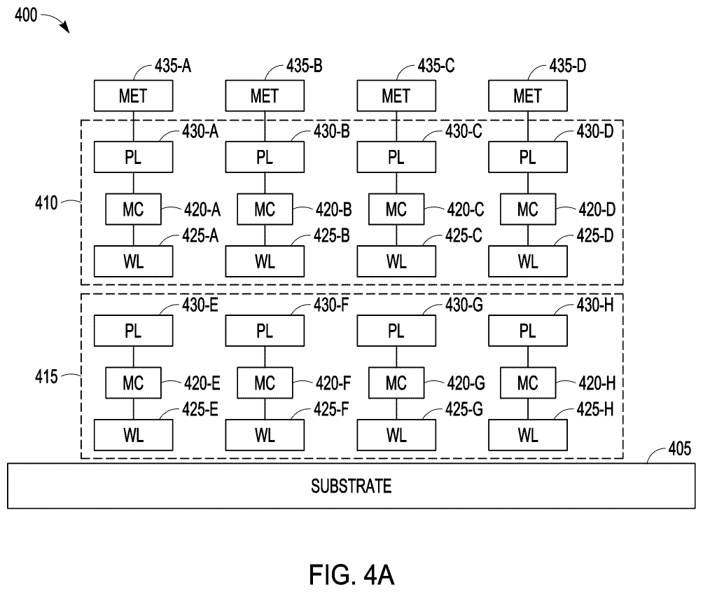

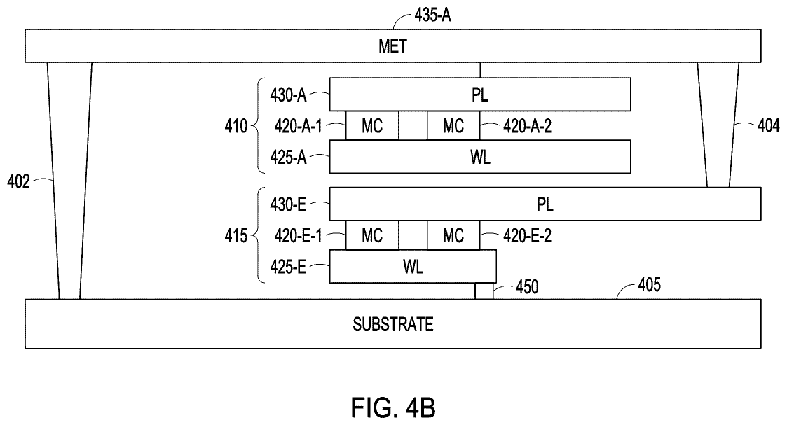

FIG. 4A illustrates an example of a first cross-section view of a portion of a first memory device 400. In the example of the memory device 100 described with reference to FIG. 1, the cross-section view of the first memory device 400 can be taken along line 4A-4A shown in FIG. 1. As such, the word lines (WL) and the plate lines (PL) of the first memory device 400 extend into or extend out of the page.

The first memory device 400 can include a substrate 405, a first deck 410 comprising some memory cells 420 of the array, and a second deck 415 comprising other memory cells 420 of the array. The second deck 415 can be positioned between the substrate 405 and the first deck 410. The first memory device 400 can be an example of the memory device 100 described with reference to FIG. 1. The first deck 410 and the second deck 415 can be examples of levels of memory cells described with reference to FIG. 1.

The first deck 410 and the second deck 415 can each include a respective plurality of memory cells 420, word lines 425, plate lines 430 and other components or access lines that are not shown. The memory cells 420 can include a capacitor (not shown) and a selection component (not shown). In some examples, a digit line (not shown) can extend perpendicularly to the word lines 425 and the plate lines 430. In some examples, depending on the array architecture, digit lines can be connected to a selection component placed between the memory cell 420 and word line 425 or placed between the memory cell 420 and the plate line 430. The memory cells 420 can be examples of the memory cells 105 described with reference to FIG. 1 and FIG. 2. In some examples, the memory cells 420 are ferroelectric memory cells. In other examples, the memory cells 420 can be dielectric memory cells. The first deck 410 and the second deck 415 are shown as having four memory cells for illustrative purposes only. A deck can include any number of memory cells and access lines. Each of the decks can be considered to include its own respective array, or the decks together can be considered to include a single array.

Each of the memory cells 420 is coupled to a word line 425 and a plate line 430. Each word line 425 can be coupled to multiple memory cells 420. Each plate line 430 can be coupled to multiple memory cells 420. For example, the word line 425-A and the plate line 430-A can extend outward from the plane of the page and couple to an additional memory cell adjacent to the memory cell 420-A. The word line 425 can be an example of the word line 110 described with reference to FIG. 1 and FIG. 2. The plate line 430 can be an example of the plate line 210 described with reference to FIG. 2.

In an example, the plate lines can be configured to bias a plurality of lines of memory cells. As such, the various plate lines can be associated with multiple digit lines. There can be a one-to-many mapping of a particular plate line to multiple the digit lines. In another example, a memory device can include a respective plate line for each digit line to provide a one-to-one mapping of plate lines to digit lines. In some examples, the plate lines of the first deck 410 and/or the second deck 415 can be formed as sheets of material that are coupled to multiple rows or columns of the memory cells 420. The plate lines can be formed of a conductive or metallic material using a variety of methods. The plate lines can be formed by deposition and patterning (e.g., etching of conductive/metallic materials or compounds).

In an example, a plate driver can be coupled to every plate line the first memory device 400. The plate drivers can be coupled to the plate lines, for example through the substrate 405, and one or more respective contacts. In some examples, the plate driver(s) can be positioned outside a footprint of the three-dimensional array of ferroelectric memory cells. Additionally or alternatively, an access line may be coupled to the plate driver and can extend from the plate driver to an edge of the footprint of the three-dimensional array. In some examples, the configurations of the plate lines can reduce the amount of die area used to connect the plate lines of the first deck 410 and/or second deck 415 to the substrate 405.

The example of the first memory device 400 includes metal layers or lines (MET). Each of the metal lines can be coupled to a respective one of the plate lines. In the illustrated example, the metal lines extend into or extend out of the page. Each metal line can be coupled to one or multiple plate lines. For example, a first metal line 435-A can extend outward from the plane of the page and couple to another plate line or to an extension of the plate line 430-A. In an example, multiple metal lines can be electrically coupled using the same or another metal layer (e.g., another metal layer above the plane of the metal lines 435). Although the illustrated example of the first memory device 400 shows the metal lines outside of, and adjacent to, the first deck 410, in other examples, the first deck 410 can include its corresponding metal lines. In an example, the second deck 415 can include corresponding metal lines. The illustrated example of the second deck 415 does not include separate metal lines.

The substrate 405 can be positioned below the second deck 415. The substrate 405 can include components to support operations of the memory cells 420. For example, the substrate 405 can include logic circuitry, decoders, amplifiers, drivers, or other circuitry. In an example, the substrate 405 comprises multiple metal, semiconductor, or other layers. Various circuitry or components can be integrated using the layers of the substrate 405.

A memory controller 140 can be coupled to the various components of the substrate 405 to perform operations using the memory cells 420. In an example, the first memory device 400 that includes multiple decks of cells can include or use various connectors that pass through intervening layers of memory cells, access lines, or decks to reach certain components. For example, the plate lines 430 can each be routed to the same or different circuitry on the substrate 405.

FIG. 4B illustrates an example of a second cross-section view of the first memory device 400, taken from a different perspective than the example of FIG. 4A. In the example of the memory device 100 described with reference to FIG. 1, the cross-section view of the first memory device 400 in FIG. 4B can be taken along line 4B-4B shown in FIG. 1. As such, the word lines, the plate lines, and the metal lines of the first memory device 400 extend horizontally across the page. In some examples, digit lines (not shown) can extend out from the plane of the page and couple to respective selection components of each memory cell (not shown).

The first memory device 400 includes the substrate 405, a portion of the first deck 410, and a portion of the second deck 415. For example, the first memory device 400 shows the memory cells 420-A from the first deck 410 and memory cells 420-E from the second deck 415 and their associated word lines 425 and plate lines 430. While the word lines 425-A, 425-E are each illustrated as being coupled to two respective memory cells (420-A-1, 420-A-2, and 420-E-1, 420-E-2), the word lines 425 and the plate lines 430 can be coupled to any number of memory cells 420. Two memory cells 420 are provided for illustrative purposes only.

A first contact 450 can couple the word line 425-E of the second deck 415 to the substrate 405. The first contact 450 can be configured to provide electronic communication between the word line 425-E and the components provided in or on the substrate 405 (e.g., decoders, amplifiers, drivers, etc.). In some examples, the first contact 450 can be an example of a via. The first contact 450 can be positioned in the first memory device 400 without disrupting or disturbing other components of the first memory device 400 (e.g., word line 425-A, plate line 430-A, or plate line 430-E).

In an example, the first deck 410 comprises or is coupled to a first metal line 435-A. For example, the plate line 430-A can be coupled to the first metal line 435-A. The first metal line 435-A can be coupled to a second contact 402. The second contact 402 can be configured to provide electronic communication between the first metal line 435-A and the components provided in or on the substrate 405 (e.g., decoders, amplifiers, drivers, etc.). In some examples, the second contact 402 can be an example of a via. In some examples, the second contact 402 can pass (e.g., vertically) through the word line 425-E or the layer comprising the word line 425-E. In some examples, the word line 425-E can be laterally terminated to allow the second contact 402 to couple the substrate 405 to the first metal line 435-A. In some examples, a pattern of memory cells 420 in the first deck 410 or the second deck 415 can be interrupted or discontinued to allow the second contact 402 to pass through to the substrate 405.

In the example of FIG. 4B, the second deck 415 comprises the plate line 430-E. The plate line 430-E can be coupled to the first metal line 435-A using a third contact 404. The third contact 404 can thus be configured to provide electronic communication between the second deck 415 and the components provided in or on the substrate 405 (e.g., decoders, amplifiers, drivers, etc.) using a signal path that includes the first metal line 435-A. In some examples, the third contact 404 can be an example of a via. Like the second contact 402, in some examples, the third contact 404 can pass through other layers or components to reach the first metal line 435-E. In some examples, the plate line 430-A, a pattern of the memory cells 420-A, the word line 425-A, or combinations thereof can be laterally terminated, interrupted, and/or discontinued to allow the third contact 404 to pass from the plate line 430-E to the first metal line 435-A.

In some examples, other conductive paths (not shown) can be configured to provide electronic communication between the support components in the substrate 405 and respective word lines 425 and/or plate lines 430 and/or digit lines. For example, these other conductive paths can include contacts or vias to higher level metal connections and contacts or vias to silicon substrates. In some examples, the various word lines, digit lines, and plate lines can be staggered in length to ensure that top decks or levels are inside a footprint of layers positioned below, rather than extending laterally outside the footprint of layers positioned below, or vice versa.

In the example of the first memory device 400, the signal path from the substrate 405 to the components of the second deck 415 can be relatively long. The relatively long signal path can be characterized in part by resistance and capacitance characteristics, among others, that can adversely affect performance or power consumption characteristics of the first memory device 400, or of a device that comprises the first memory device 400. For example, a plate drive signal generated by components on the substrate 405 can be delivered to the second deck 415 using a signal path that includes at least the second contact 402, the first metal line 435-A, and the third contact 404. Such a plate drive signal can have a sufficiently large signal magnitude to ensure that the correct voltage is available at the plate line 430-E of the second deck 415.

In additional to path length-related issues, there can be signal routing and congestion issues with the example of the first memory device 400. In some examples, digit line contacts for the first deck 410 are routed to the substrate 405 at a first side of the array. Plate line drive contacts for the second deck 415 can be routed along another side of the array to avoid the digit line contacts. This routing occupies additional socket space and creates routing congestion. The congested routing can impact the power delivery network for the device, for example, because power line widths may be reduced to accommodate the plate line drive contacts.

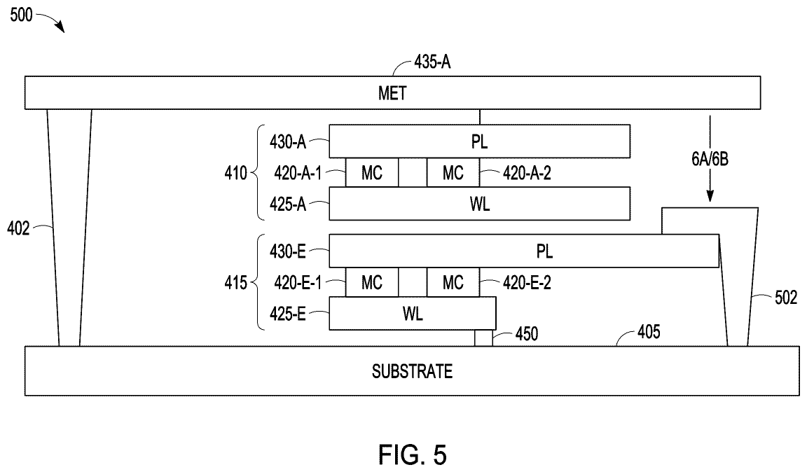

FIG. 5 illustrates an example of a cross-section view of a portion of a second memory device 500 with improved plate drive signal routing. The second memory device 500 can comprise an example of a memory array with several of the same or similar components as described herein for the first memory device 400. Like numerals are used to refer to like components in the various embodiments of the memory arrays and devices discussed herein.

The illustrated example of the second memory device 500 is taken from the same perspective as the example of FIG. 4B. Accordingly, the word lines, the plate lines, and the metal lines of the first memory device 400 extend horizontally across the page. In some examples, digit lines (not shown) can extend out from the plane of the page and couple to respective selection components of each memory cell (not shown).

The second memory device 500 includes the substrate 405, a portion of the first deck 410, and a portion of the second deck 415. Specifically, the second memory device 500 shows the memory cells 420-A from the first deck 410 and memory cells 420-E from the second deck 415 and their associated word lines 425 and plate lines 430.

A first contact 450 can couple the word line 425-E of the second deck 415 to the substrate 405. The first contact 450 can be configured to provide electronic communication between the word line 425-E and the components provided in or on the substrate 405 (e.g., decoders, amplifiers, drivers, etc.).

In an example, the first deck 410 comprises or is coupled to the first metal line 435-A. For example, the plate line 430-A of the first deck 410 can be coupled to the first metal line 435-A. The first metal line 435-A can be coupled to the second contact 402. The second contact 402 can be configured to provide electronic communication between the first metal line 435-A and the components provided in or on the substrate 405 (e.g., decoders, amplifiers, drivers, etc.). In some examples, the second contact 402 can be an example of a via. In some examples, the second contact 402 can pass through the word line 425-E or a layer that comprises the word line 425-E. In some examples, the plate lines of the first deck 410 are routed to the substrate 405 exclusively using the second contact 402, or using multiple instances of the second contact 402 that respectively correspond to the plate lines of the first deck 410.

In the example of FIG. 5, the second deck 415 comprises the plate line 430-E, and the plate line 430-E can be coupled to components in the substrate 405 using an overlapping contact 502. That is, the overlapping contact 502 can provide electronic communication between the plate lines, or other components, of the second deck 415 and the components provided in or on the substrate 405 (e.g., decoders, amplifiers, drivers, etc.). In some examples, the overlapping contact 502 can be an example of a via. Like the second contact 402, in some examples, the overlapping contact 502 can pass (e.g., vertically) through or adjacent to other layers or components of the second memory device 500 to reach the substrate 405. In an example, one or more components or layers of the first deck 410 can be provided on or over the overlapping contact 502 (e.g., in the area between the top of the second deck 415 and the first metal line 435-A). For example, some of the memory cells of the first deck 410 can be provided above the overlapping contact 502. That is, a footprint of at least a portion of the first deck 410 can extend over the second deck 415, and can optionally extend over the overlapping contact 502 as well.

In an example, the overlapping contact 502 is considered to be a “partially-on, partially-off” contact with respect to the second deck 415 plate line 430-E. The partially-on portion of the contact overlays and is in physical contact with an upper surface of the plate line 430-E. The partially-off portion of the contact extends laterally away from a side edge of the plate line 430-E, and away from the memory cell region of the second deck 415. For example, about half of an upper portion of the overlapping contact 502 can overlay or overlap with the plate line 430-E, and another half of the upper portion of the overlapping contact 502 can extend away from the edge of the plate line.

Relative to the example of the first memory device 400 and the third contact 404, the signal path length from the substrate 405 to the plate line 430-E of the second deck 415 can be reduced using the overlapping contact 502. Accordingly, the signal path in the second memory device 500 that includes the overlapping contact 502 can be characterized in part by relatively lower resistance and capacitance characteristics, among others, relative to the same characteristics for the signal path that includes the third contact 404 in the first memory device 400. For example, a plate drive signal generated by components on the substrate 405 can be routed to the second deck 415 using a direct signal path that includes the overlapping contact 502. Accordingly, the plate drive signal can have a relatively lower signal magnitude than is used in the example of the first memory device 400.

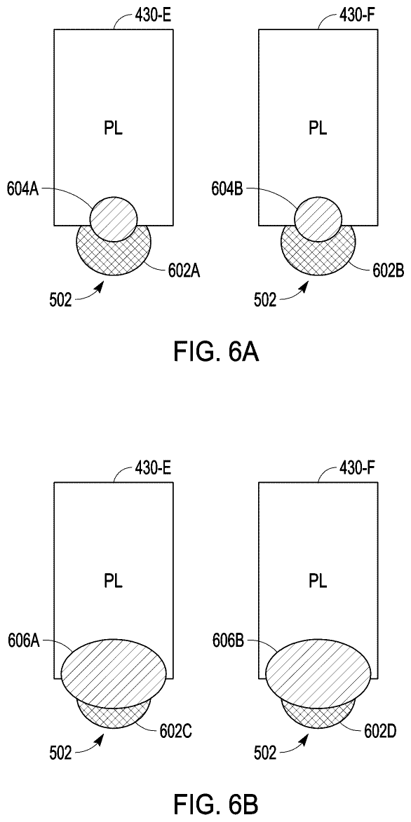

FIG. 6A and FIG. 6B illustrate generally examples of top views of a portion of the second memory device 500. The depicted views can be taken from line 6A/6B shown in FIG. 5. The views are top views of a pair of adjacent plate lines of the second deck 415 of the second memory device 500 and respective instances of the overlapping contact 502 that are coupled to each of the plate lines. FIG. 6A shows a first example configuration of the overlapping contacts 502, and FIG. 6B shows a different second example configuration of the overlapping contacts 502. Other configurations can similarly be used.

The example of FIG. 6A shows the plate line 430-E and another plate line 430-F of the second deck 415 of the second memory device 500. The plate lines 430-E, 430-F can be adjacent lines. Respective instances of the overlapping contact 502 can be provided or formed adjacent to side edges of the metal lines. That is, each plate line can have at least one corresponding overlapping contact 502 that couples the plate line to other layers or circuitry of the second memory device 500, such as at the substrate 405 or at another lower layer relative to the plate line.

Each instance of the overlapping contact 502 can include a lower portion and an upper portion. The lower portion of the overlapping contact 502 can extend down from the corresponding plate line layer toward the substrate 405, as shown in FIG. 5. The upper portion of the overlapping contact 502 can electrically couple the lower portion of the overlapping contact 502 to the corresponding metal line. In some examples, the lower and upper portions of a particular contact are formed in one continuous process such that there is no boundary between the portions of the contact. In other examples, the lower portion can be formed first (e.g., using a first process), and then the upper portion of the same contact can be formed second (e.g., using the same process or a different second process) to ensure a robust electrical connection is provided between the lower portion of the contact and the corresponding plate line (or other line or layer).

In FIG. 6A, at left, an example of a first overlapping contact 502 instance includes a lower portion 602a and an upper portion 604a. The lower portion 602a and the upper portion 604a can be formed using the same or different processes, and can be electrically coupled to each other. In an example, the lower portion 602a can be coupled to the substrate 405, or to another layer or contact below the plate line 430-E (e.g., as shown in FIG. 5). The upper portion 604a can be coupled to the plate line 430-E. In the example of FIG. 6A, a cross-sectional area of the lower portion 602a is greater than a cross-sectional area of the upper portion 604a. In the example of FIG. 6A, the cross-sectional area of the lower portion 602a is less than a width of the plate line 430-E. Other dimensions and sizes can similarly be used.

FIG. 6A, at right, shows an example of a second overlapping contact 502 instance with a lower portion 602b and an upper portion 604b. The example of the first and second overlapping contacts 502 in FIG. 6A are provided to show that multiple instances of the overlapping contacts 502 can be provided for respective plate lines of a deck. The various instances of the overlapping contacts 502 can be electrically separate from each other, for example, at least in the plane of the plate lines 430.

FIG. 6B includes an example of a third overlapping contact 502 instance (left) and a fourth overlapping contact 502 instance (right). The third overlapping contact 502 includes a lower portion 602c and an upper portion 606a, and the fourth overlapping contact 502 includes a lower portion 602d and an upper portion 606b. In the example of FIG. 6B, a cross-sectional area of the upper portion 606a is greater than a cross-sectional area of the lower portion 602c. Various sizes or relationships between the upper and lower portions of the contacts can be used depending on, for example, an accuracy of the process used to form the contacts.

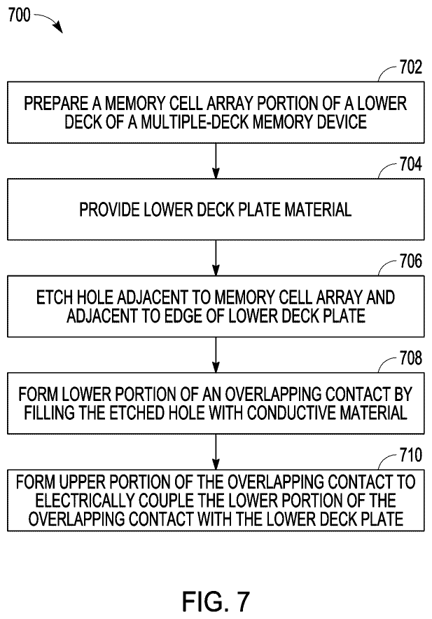

FIG. 7 illustrates generally an example of a first method 700 that can include forming an overlapping contact, such as the overlapping contact 502 of the example of FIG. 5, that extends from an upper plate line of a memory array deck to a lower layer or substrate of the deck of a memory device, such as the memory device 100 of FIG. 1, the second memory device 500 of FIG. 5, or one or more other memory devices. In an example, the overlapping contact can be coupled at a first end or proximal end to a plate line, or to a metal line that is coupled to a plate line, and the overlapping contact can be coupled at an opposite second end or distal end to another contact or to drive circuitry at a substrate for the memory array.

At operation 702, the first method 700 includes preparing a memory cell array portion of a lower deck of a multiple-deck memory device. In an example, the operation 702 includes preparing or fabricating one or more layers of FeRAM memory cells. In an example, operation 702 can optionally include preparing array portions of one or more other decks of the same memory device. In a particular example, operation 702 includes preparing the second deck 415 of the first memory device 400.

At operation 704, the first method 700 includes providing a lower deck plate material. The operation 704 can include depositing a conductive layer and forming plate lines or plate layers of the memory array in the lower deck. For example, operation 704 can include providing or forming the plate lines 430.

At operation 706, the first method 700 includes etching a hole adjacent to, and outside of a footprint of, the memory cell array portion of the lower deck of the memory device. In an example, the hole can be etched adjacent to a side edge of the lower deck plate that was provided at operation 704. The etched hole can extend, for example, from a surface or plane of the plate layer to a lower layer of the deck, or to the substrate upon which the lower deck is formed or to which the lower deck is coupled. Referring again to FIG. 5, the hole can be formed adjacent to the second deck 415, such as at a side edge of the plate line 430-E, and can extend to the substrate 405.

At operation 708, the first method 700 includes forming a lower portion of an overlapping contact by filling the etched hole with a conductive material. The conductive material filler can extend from a bottom of the hole (e.g., at the substrate) to the surface or plane of the plate layer. In an example, operation 708 includes forming a portion of the overlapping contact 502 that extends between the plate line 430-E and the substrate 405.

At operation 710, the first method 700 can include forming an upper portion of the overlapping contact. For example, operation 710 can include forming a portion of the overlapping contact 502 that couples the lower portion to the plate line 430-E.

In an example, the operation 708 and the operation 710 comprise portions of one continuous operation and there is no boundary between the upper and lower portions of the overlapping contact. In another example, the operation 710 includes depositing the same or different conductive material to a region that overlaps the lower portion of the contact and overlaps at least a portion of a surface (e.g., a top surface, side surface, etc.) of the plate layer. Following the operation 710, the plate layer is reliably and robustly electrically coupled to the lower portion of the overlapping contact.

In an example, multiple instances of the overlapping contacts can be formed together or in parallel. For example, operation 706 can include etching multiple holes adjacent to respective plate lines of the lower deck. Operation 708 can include forming respective lower portions of the multiple contacts by filling the multiple holes formed at operation 706. Operation 710 can include forming respective upper portions of the contacts to complete formation of the multiple overlapping contact instances.

To better illustrate the multiple-deck memory devices and plate line connection techniques and configurations discussed herein, a non-limiting set of Example embodiments are set forth below as numerically identified Examples.
Example 1 is an apparatus, comprising: a memory array comprising an upper deck of memory cells and a lower deck of memory cells positioned between the upper deck of memory cells and a substrate, each memory cell of the upper deck of memory cells and the lower deck of memory cells comprising a respective charge storage component and a respective selection component; a first plate line associated with the lower deck of memory cells and coupled with charge storage components of the lower deck of memory cells, wherein the first plate line is positioned between the lower deck of memory cells and the upper deck of memory cells; and a first contact including an upper contact portion and a lower contact portion, wherein the upper contact portion is coupled to the first plate line and extends laterally away from the first plate line and the lower deck of memory cells, and wherein the lower contact portion is coupled between the upper contact portion and the substrate.
In Example 2, the subject matter of Example 1 optionally includes each of the upper deck of memory cells and the lower deck of memory cells comprises ferroelectric random access memory (FeRAM) memory cells.
In Example 3, the subject matter of any one or more of Examples 1-2 optionally includes the upper deck of memory cells extends over an upper surface of the first contact.
In Example 4, the subject matter of any one or more of Examples 1-3 optionally includes the upper contact portion of the first contact is coupled to a top surface of the first plate line.
In Example 5, the subject matter of Example 4 optionally includes the first contact extends around a lateral side edge of the first plate line.
In Example 6, the subject matter of any one or more of Examples 4-5 optionally includes the lower contact portion of the first contact comprises a via that extends vertically from the upper contact portion to first plate driver circuitry in the substrate.
In Example 7, the subject matter of Example 6 optionally includes the first plate driver circuitry.
In Example 8, the subject matter of Example 7 optionally includes a second plate line associated with the upper deck of memory cells, and a second contact that electrically couples the second plate line to the substrate, wherein the second contact extends vertically in a region adjacent to the lower deck of memory cells.
In Example 9, the subject matter of Example 8 optionally includes the first contact is disposed adjacent to a first side of the lower deck of memory cells and the second contact is disposed adjacent to a different second side of the lower deck of memory cells.
In Example 10, the subject matter of any one or more of Examples 1-9 optionally includes a horizontal cross-sectional area of the upper contact portion of the first contact exceeds a horizontal cross-sectional area of the lower contact portion of the first contact.
In Example 11, the subject matter of any one or more of Examples 1-10 optionally includes a plate driver configured to adjust a voltage of the first plate line, wherein the plate driver is coupled to the substrate, and wherein the plate driver is coupled to the first plate line using the first contact.
In Example 12, the subject matter of Example 11 optionally includes the plate driver is positioned outside a footprint of the lower deck of memory cells.
Example 13 is a method comprising: providing a lower deck portion of a memory device, the lower deck portion comprising memory cells of a first type, and memory cells of the lower deck portion are coupled to a lower deck plate line; forming a hole adjacent to a side edge of the lower deck plate line and adjacent to the memory cells of the first type, wherein the hole extends through one or more layers of the lower deck portion of the memory device below the lower deck plate line; forming a lower portion of an overlapping contact by filling the hole with a first conductive material; and forming an upper portion of the overlapping contact, wherein the upper portion of the overlapping contact electrically couples the lower portion of the overlapping contact with the lower deck plate line.
In Example 14, the subject matter of Example 13 optionally includes forming the upper portion of the overlapping contact comprising depositing a second conductive material on an upper surface of the lower deck plate line and on an upper surface of the lower portion of the overlapping contact.
In Example 15, the subject matter of any one or more of Examples 13-14 optionally includes providing an upper deck portion of the memory device, the upper deck portion comprising memory cells of a second type, wherein at least a portion of the memory cells of the second type are disposed over the upper portion of the overlapping contact.
In Example 16, the subject matter of any one or more of Examples 13-15 optionally includes forming the lower portion of the overlapping contact comprising electrically coupling the lower portion of the overlapping contact with drive circuitry in a substrate for the memory device.
In Example 17, the subject matter of any one or more of Examples 13-16 optionally includes forming the lower portion of the overlapping contact comprising depositing the first conductive material adjacent to a lateral side edge of the lower deck plate line.
Example 18 is a memory device comprising: a device substrate; a lower deck of memory cells comprising memory cells of a first type, the lower deck of memory cells positioned on the device substrate; an upper deck of memory cells comprising memory cells of a second type, the upper deck of memory cells positioned over at least a portion of the lower deck of memory cells; a first plate line coupled with charge storage components of the lower deck of memory cells, wherein the first plate line is positioned between the lower deck of memory cells and the upper deck of memory cells; and an overlapping contact including an upper contact portion and a lower contact portion, wherein the upper contact portion is coupled to the first plate line and the lower contact portion is coupled to the upper contact portion and drive circuitry in the substrate.
In Example 19, the subject matter of Example 18 optionally includes the upper contact portion of the overlapping contact extends laterally away from the first plate line and from the lower deck of memory cells.
In Example 20, the subject matter of any one or more of Examples 18-19 optionally includes the upper deck of memory cells comprises ferroelectric random access memory (FeRAM) memory cells and the lower deck of memory cells comprises FeRAM memory cells.
Example 21 is an apparatus comprising means to implement of any of any one or more of Examples 1-20.
Example 22 is a system to implement of any of any one or more of Examples 1-20.
Example 23 is a method to implement of any of any one or more of Examples 1-20.

Each of these non-limiting examples can stand on its own or can be combined in various permutations or combinations with one or more of the other examples.

The various illustrative blocks and modules described in connection with the disclosure herein can be implemented or performed at least in part with a general-purpose processor, a DSP, an ASIC, an FPGA or other programmable logic device, discrete gate or transistor logic, discrete hardware components, or any combination thereof designed to perform the functions described herein. A general-purpose processor can be a microprocessor, but in the alternative, the processor can be any conventional processor, controller, microcontroller, or state machine. A processor can be implemented as a combination of computing devices (e.g., a combination of a digital signal processor (DSP) and a microprocessor, multiple microprocessors, one or more microprocessors in conjunction with a DSP core, or any other such configuration).

Functions described herein, such as including memory device operation, can be implemented in hardware, software executed by a processor, firmware, or any combination thereof. If implemented in software executed by a processor, the functions can be stored on or transmitted over as one or more instructions or code on a computer-readable medium. Other examples and implementations are within the scope of the disclosure and appended claims. For example, due to the nature of software, functions described above can be implemented using software executed by a processor, hardware, firmware, hardwiring, or combinations of any of these. Features implementing functions can be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium can be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An apparatus, comprising:
a memory array comprising an upper deck of memory cells and a lower deck of memory cells positioned between the upper deck of memory cells and a substrate, each memory cell of the upper deck of memory cells and the lower deck of memory cells comprising a respective charge storage component and a respective selection component;
a first plate line associated with the lower deck of memory cells and coupled with charge storage components of the lower deck of memory cells, wherein the first plate line is positioned between the lower deck of memory cells and the upper deck of memory cells; and
a first contact including an upper contact portion and a lower contact portion, wherein the upper contact portion is coupled to the first plate line and extends laterally away from the first plate line and the lower deck of memory cells, and wherein the lower contact portion is coupled between the upper contact portion and the substrate.

2. The apparatus of claim 1, wherein each of the upper deck of memory cells and the lower deck of memory cells comprise ferroelectric random access memory (FeRAM) memory cells.

3. The apparatus of claim 1, wherein the upper deck of memory cells extends over an upper surface of the first contact.

4. The apparatus of claim 1, wherein the upper contact portion of the first contact is coupled to a top surface of the first plate line.

5. The apparatus of claim 4, wherein the first contact extends around a lateral side edge of the first plate line.

6. The apparatus of claim 4, wherein the lower contact portion of the first contact comprises a via that extends vertically from the upper contact portion to first plate driver circuitry in the substrate.

7. The apparatus of claim 6, comprising the first plate driver circuitry.

8. The apparatus of claim 7, comprising:
a second plate line associated with the upper deck of memory cells;
a second contact that electrically couples the second plate line to the substrate, wherein the second contact extends vertically in a region adjacent to the lower deck of memory cells.

9. The apparatus of claim 8, wherein the first contact is disposed adjacent to a first side of the lower deck of memory cells and the second contact is disposed adjacent to a different second side of the lower deck of memory cells.

10. The apparatus of claim 1, wherein a horizontal cross-sectional area of the upper contact portion of the first contact exceeds a horizontal cross-sectional area of the lower contact portion of the first contact.

11. The apparatus of claim 1, comprising a plate driver configured to adjust a voltage of the first plate line, wherein the plate driver is coupled to the substrate, and wherein the plate driver is coupled to the first plate line using the first contact.

12. The apparatus of claim 11, wherein the plate driver is positioned outside a footprint of the lower deck of memory cells.

13. A method comprising:
providing a lower deck portion of a memory device, the lower deck portion comprising memory cells of a first type, and memory cells of the lower deck portion are coupled to a lower deck plate line;
forming a hole adjacent to a side edge of the lower deck plate line and adjacent to the memory cells of the first type, wherein the hole extends through one or more layers of the lower deck portion of the memory device below the lower deck plate line;
forming a lower portion of an overlapping contact by filling the hole with a first conductive material; and
forming an upper portion of the overlapping contact, wherein the upper portion of the overlapping contact electrically couples the lower portion of the overlapping contact with the lower deck plate line.

14. The method of claim 13, wherein forming the upper portion of the overlapping contact comprises depositing a second conductive material on an upper surface of the lower deck plate line and on an upper surface of the lower portion of the overlapping contact.

15. The method of claim 13, comprising providing an upper deck portion of the memory device, the upper deck portion comprising memory cells of a second type, wherein at least a portion of the memory cells of the second type are disposed over the upper portion of the overlapping contact.

16. The method of claim 13, wherein forming the lower portion of the overlapping contact comprises electrically coupling the lower portion of the overlapping contact with drive circuitry in a substrate for the memory device.

17. The method of claim 13, wherein forming the lower portion of the overlapping contact comprises depositing the first conductive material adjacent to a lateral side edge of the lower deck plate line.

18. A memory device comprising:
a device substrate;
a lower deck of memory cells comprising memory cells of a first type, the lower deck of memory cells positioned on the device substrate;
an upper deck of memory cells comprising memory cells of a second type, the upper deck of memory cells positioned over at least a portion of the lower deck of memory cells;
a first plate line coupled with charge storage components of the lower deck of memory cells, wherein the first plate line is positioned between the lower deck of memory cells and the upper deck of memory cells; and
an overlapping contact including an upper contact portion and a lower contact portion, wherein the upper contact portion is coupled to the first plate line and the lower contact portion is coupled to the upper contact portion and drive circuitry in the substrate.

19. The memory device of claim 18, wherein the upper contact portion of the overlapping contact extends laterally away from the first plate line and the lower deck of memory cells.

20. The memory device of claim 18, wherein the upper deck of memory cells comprises ferroelectric random access memory (FeRAM) memory cells and the lower deck of memory cells comprises FeRAM memory cells.
